(19) United States
(12) Patent Application Publication
(10) Pub. No.: US 2019/0189578 A1
(43) Pub. Date: Jun. 20, 2019

(54) FINGERPRINT CHIP PACKAGING METHOD AND FINGERPRINT CHIP PACKAGE

(71) Applicant: China Wafer Level CSP Co., Ltd., Suzhou (CN)

(72) Inventor: Zhiqi Wang, Suzhou (CN)

(73) Assignee: China Wafer Level CSP Co., Ltd., Suzhou (CN)

(21) Appl. No.: 16/209,695

(22) Filed: Dec. 4, 2018

(30) Foreign Application Priority Data
Dec. 18, 2017 (CN) 201711364000.X
Dec. 18, 2017 (CN) 201721773042.4

(51) Int. Cl. H01L 23/00; H01L 25/065; H01L 21/78; G06K 9/00

(52) U.S. Cl. CPC H01L 24/13; H01L 25/0655; G06K 9/00006; H01L 21/78; H01L 24/95

(57) ABSTRACT

A fingerprint chip packaging method and a fingerprint chip package are provided. During a process of packaging a fingerprint chip, the fingerprint chip is directly packaged and protected by a mold compound layer to form a thin package. With the fingerprint chip packaging method and the fingerprint chip package, the thickness of the package is greatly reduced, which facilitates miniaturization of the electronic device. Further, since the mold compound layer formed after curing of a mold compound material has a great mechanical strength, the mold compound layer can serve as a carrier substrate for mounting other electronic components of the electronic device, such that the integration of the electronic device is greatly improved, the space of the circuit board is saved, thereby facilitating the miniaturization of the electronic device.

This application claims priorities to Chinese Patent Application No. 201711364000.X, titled “FINGERPRINT CHIP PACKAGING METHOD AND FINGERPRINT CHIP PACKAGE”, filed on Dec. 18, 2017 with the Chinese Patent Office, and Chinese Patent Application No. 201721773042.4, tided “FINGERPRINT CHIP PACKAGE”, filed on Dec. 18, 2017 with the Chinese Patent Office, which are incorporated herein by reference in their entireties.

### FIELD

The present disclosure relates to the technical field of chip packaging, and in particular to a fingerprint chip packaging method and a fingerprint chip package.

### BACKGROUND

With the continuous development of technology, more and more electronic devices having fingerprint recognition functions are widely applied in and bring great convenience to people's daily life and work. These electronic devices become indispensable to people currently.

A main component for implementing the fingerprint recognition function in an electronic device is a fingerprint chip. In order to prevent damage to the fingerprint chip and facilitate electrical connection between the fingerprint chip to the main board of the electronic device, it is generally required to package the fingerprint chip to form a package.

In the fingerprint chip packaging process in the conventional technology, the fingerprint chip is generally arranged opposite to a circuit board, is attached with the circuit board by an adhesive layer, and is electrically connected to the circuit board via a solder wire. In this case, the formed fingerprint recognition chip package is thick, which is contrary to miniaturization of the electronic device.

### SUMMARY

In order to solve the above problems, a fingerprint chip packaging method and a fingerprint chip package are provided according to technical solutions of the present disclosure, with which a thickness of the fingerprint chip package can be reduced, and miniaturization of the electronic device is facilitated.

The following technical solutions are provided in the present disclosure.

A fingerprint chip packaging method is provided. The fingerprint chip packaging method includes: providing multiple fingerprint chips arranged in an array on a carrier substrate, where each of the fingerprint chips has a front surface and a back surface opposite to each other, a sensing unit and a contact pad electrically connected to the sensing unit are provided on the front surface of the fingerprint chip, a solder bump electrically connected to the contact pad is provided on the back surface of the fingerprint chip, the solder bump faces upwards, and cutting trenches are arranged between adjacent ones of the fingerprint chips; forming a mold compound layer covering the multiple fingerprint chips; grinding the mold compound layer to expose the solder bump to facilitate electrical connection between the solder bump and an external circuit; and dividing the mold compound layer along the cutting trenches to form multiple packages.

In an embodiment, in the above fingerprint chip packaging method, an adhesive film is provided on a surface of the carrier substrate, and the fingerprint chips are secured to the carrier substrate by the adhesive film.

In an embodiment, in the above fingerprint chip packaging method, the providing the multiple fingerprint chips arranged in an array on the carrier substrate includes: preparing a packaging substrate, where the packaging substrate is provided with multiple receiving holes arranged in an array, and providing one fingerprint chip in each of the receiving holes, where the solder bump protrudes from a surface of the packaging substrate, and the mold compound layer covers the packaging substrate, and the receiving holes are filled with the mold compound layer.

In an embodiment, in the above fingerprint chip packaging method, the providing one fingerprint chip in each of the receiving holes includes: providing an adhesive film on a surface of the packaging substrate facing the carrier substrate, where the fingerprint chips are secured by the adhesive film.

In an embodiment, the above fingerprint chip packaging method further includes: removing the adhesive film after the grinding and before the cutting; or removing the adhesive film after the cutting.

In an embodiment, in the above fingerprint chip packaging method, the fingerprint chips are capacitive fingerprint chips, and a front surface of each of the fingerprint chips in the packages is covered with a protection layer having a dielectric constant greater than 7.

In an embodiment, the above fingerprint chip packaging method further includes: inverting the mold compound layer in which the multiple fingerprint chips are secured after the grinding, so that the front surface of each of the fingerprint chips faces upwards; and forming the protection layer covering the fingerprint chips and the mold compound layer.

In an embodiment, in the above fingerprint chip packaging method, the providing the multiple fingerprint chips arranged in an array on the carrier substrate includes: preparing the multiple fingerprint chips, with the front surface of each of the fingerprint chips being covered with the protection layer.

In an embodiment, in the above fingerprint chip packaging method, the packaging substrate has a first surface and a second surface, and the providing one fingerprint chip in each of the receiving holes includes: arranging the fingerprint chip in the receiving hole, with an end surface of the fingerprint chip corresponding to the front surface being flush with the first surface, and the solder bump protruding from the second surface.

In an embodiment, in the above fingerprint chip packaging method, the packaging substrate includes a base configured to carry a mold compound material for forming the mold compound layer.

In an embodiment, in the above fingerprint chip packaging method, the packaging substrate further includes multiple interconnection circuits provided on a surface of the base, the multiple interconnection circuits are in one-to-one correspondence with the fingerprint chips, and are configured to be electrically connected to an external circuit and/or electronic component.

In an embodiment, in the above fingerprint chip packaging method, the packaging substrate is a silicon substrate or a printed circuit board (PCB).

In an embodiment, in the above fingerprint chip packaging method, the providing the multiple fingerprint chips arranged in an array on the carrier substrate includes: preparing a wafer, where the wafer is provided with multiple fingerprint chips arranged in an array, cutting gaps are provided between adjacent ones of the fingerprint chips, and the contact pad and the sensing unit are provided on the front surface of each of the fingerprint chips; forming a through hole by which the contact pad is exposed on the back surface of each of the fingerprint chips by an etching process; forming an insulating layer on the back surface of each of the fingerprint chips, where the insulating layer covers a sidewall of the through hole; forming a rewiring layer on a surface of the insulating layer, where the rewiring layer is electrically connected to the contact pad at a bottom of the through hole and is extended outside the through hole; forming a solder mask on a surface of the rewiring layer, where an opening is provided in the solder mask to expose the rewiring layer, and the solder hump is located in the opening and is electrically connected to the rewiring layer; and cutting the wafer along the cutting gaps to form the multiple fingerprint chips.

A fingerprint chip package is provided according to the present disclosure. The fingerprint chip package includes a fingerprint chip and a mold compound layer.

The fingerprint chips include a front surface and a back surface opposite to each other, a sensing unit and a contact pad electrically connected to the sensing unit are provided on the front surface of the fingerprint chip, and a solder bump electrically connected to the contact pad is provided on the back surface of the fingerprint chip.

The mold compound layer covers a side surface and the hack surface of the fingerprint chip, where the solder bump is exposed by the mold compound layer,

In an embodiment, the above fingerprint chip package further includes: a packaging substrate provided with a receiving hole. The fingerprint chip is located in the receiving hole, the solder bump is located outside the receiving hole, the mold compound layer covers a surface of the packaging substrate by which the solder bump is exposed, and the receiving hole is filled with the mold compound layer.

In an embodiment, the above fingerprint chip package further includes: a protection layer having a dielectric constant greater than a set threshold, where the protection layer covers the front surface of the fingerprint chip.

In an embodiment, in the above fingerprint chip package, the protection layer further covers a surface of the packaging substrate corresponding to the front surface of the fingerprint chip.

In an embodiment, in the above fingerprint chip package, the set threshold is greater than or equal to 7.

In an embodiment, in the above fingerprint chip package, the packaging substrate has a first surface and a second surface, an end surface of the fingerprint chip corresponding to the front surface is flush with the first surface, and the solder bump is exposed by the second surface.

In an embodiment, in the above fingerprint chip package, the packaging substrate includes a base carrying a mold compound material for forming the mold compound layer.

In an embodiment, in the above fingerprint chip package, the packaging substrate further includes an interconnection circuit provided on a surface of the base, and the interconnection circuit is configured to be electrically connected to an external circuit and/or electronic component.

In an embodiment, in the above fingerprint chip package, a through hole is provided on the back surface of the fingerprint chip, and the fingerprint chip package further includes: an insulation layer covering a sidewall of the through hole, a rewiring layer covering the insulating layer, where the rewiring layer is electrically connected to the contact pad at a bottom of the through hole and is extended outside the through hole, and a solder mask covering the rewiring layer, where an opening is provided in the solder mask to expose the rewiring layer, and the solder bump is located in the opening and is electrically connected to the rewiring layer.

In an embodiment, in the above fingerprint chip package, the packaging substrate is a silicon substrate or a printed circuit board (PCB).

According to the above description, in the fingerprint chip packaging method and the fingerprint chip package according to the technical solutions of the present disclosure, during the process of packaging the fingerprint chip, the fingerprint chip is protected by the mold compound layer, such that the formed package has a less thickness as compared with the packaging process in the conventional technology where the fingerprint chip is secured to a circuit board. With the technical solutions according to the embodiments of the present disclosure, the thickness of the package is greatly reduced, which facilitates miniaturization of the electronic device. Further, since the mold compound layer formed after curing of the mold compound material has a great mechanical strength, the mold compound layer can serve as a carrier substrate for mounting other electronic components of the electronic device, such that the integration of the electronic device is greatly improved, the space of the circuit board is saved, thereby facilitating the miniaturization of the electronic device.

### BRIEF DESCRIPTION OF THE DRAWINGS

In order to more clearly illustrate technical solutions in embodiments of the present disclosure or in the conventional technology, the drawings used to describe the embodiments or the conventional technology are briefly described hereinafter. It is apparent that the drawings in the following description show only some embodiments of the present disclosure, and other drawings may be obtained by those skilled in the art based on the drawings without any creative efforts.

FIGS. 1 to 5b are schematic diagrams showing a procedure of a fingerprint chip packaging method according to an embodiment of the present disclosure;

FIGS. 6 to 13 are schematic diagrams showing a procedure of a fingerprint chip packaging method according to another embodiment of the present disclosure;

FIGS. 14 to 16 are schematic diagrams showing a procedure of a fingerprint chip packaging method according to another embodiment of the present disclosure;

FIGS. 17 to 24 are schematic diagrams showing a procedure of a method for fabricating a fingerprint chip according to an embodiment of the present disclosure;

FIG. 25 is a schematic structural diagram showing a fingerprint chip package according to an embodiment of the present disclosure;

FIG. 26 is a schematic structural diagram showing a fingerprint chip package according to another embodiment of the present disclosure;

FIG. 27 is a schematic structural diagram showing a fingerprint chip package according to another embodiment of the present disclosure; and

FIG. 28 is a schematic structural diagram of an interconnection structure on a back surface of a fingerprint chip according to an embodiment of the present disclosure.

### DETAILED DESCRIPTION OF EMBODIMENTS

Technical solutions of embodiments of the present disclosure are clearly and completely described hereinafter in conjunction with the drawings of the embodiments of the present disclosure. It is apparent that the embodiments described in the following are only some embodiments of the present disclosure, rather than all the embodiments. Any other embodiments obtained by those skilled in the art based on the embodiments in the present disclosure without any creative efforts fall in the scope of protection of the present disclosure.

To make the above objects, features and advantages of the present disclosure more apparent and easier to be understood, the disclosure is illustrated in detail in conjunction with the drawings and specific embodiments hereinafter.

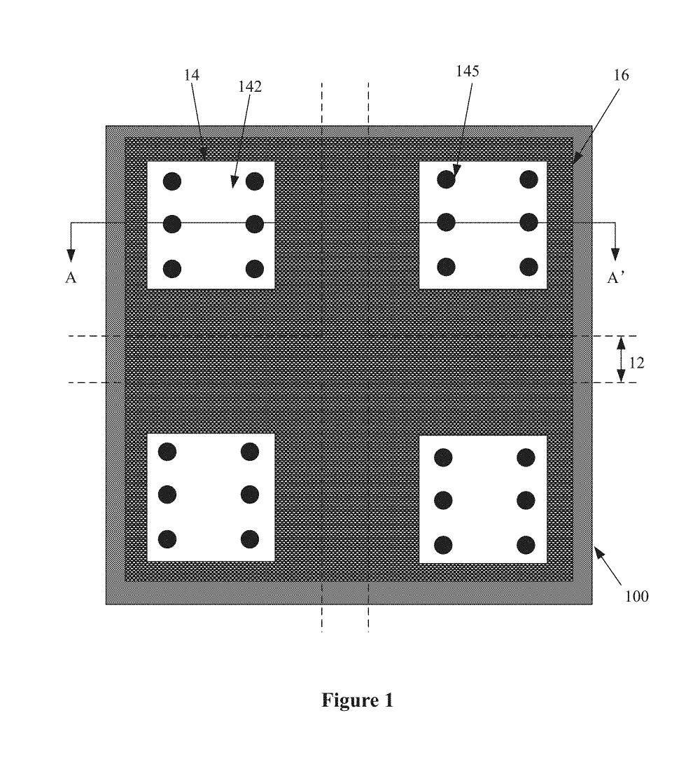

Reference is made to FIGS. 1 to 5a, which are schematic diagrams showing a procedure of a fingerprint chip packaging method according to an embodiment of the present disclosure. The fingerprint chip packaging method includes the following steps S11 to S14.

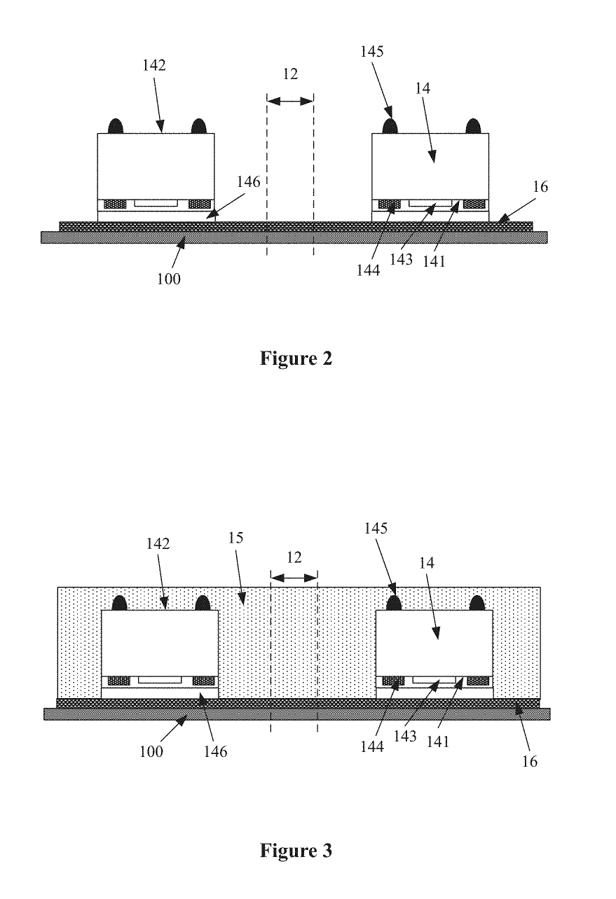

In step S11, as shown in FIG. 1 and FIG. 2, multiple fingerprint chips 14 arranged in an array are provided on a carrier substrate 100.

FIG. 1 is a top view showing back surfaces 142 of the fingerprint chips 14, and FIG. 2 is a sectional view taken along a line A-A′ in FIG. 1. In FIG. 1 and FIG. 2, only four fingerprint chips 14 are illustrated as an example. The number of fingerprint chips 14 is not limited in the embodiment of the present disclosure. Each fingerprint chip 14 has a front surface 141 and a back surface 142 opposite to each other. The fingerprint chip 14 further has a side surface. A sensing unit 143 and a contact pad 144 electrically connected to the sensing unit 143 are provided on the front surface 141 of the fingerprint chip 14. A solder bump 145 electrically connected to the contact pad 144 is provided on the back surface 142 of the fingerprint chip 14. The solder bump 145 faces upwards. Cutting trenches 12 are provided between adjacent ones of the fingerprint chips 14.

In this embodiment, a protection layer 146 having a high dielectric constant is further provided on the front surface 141 of each of the fingerprint chips 14. The protection layer covers the contact pad 144 and the sensing unit 143. The protection layer 146 serves as an outer surface of each fingerprint chip 14 at the side of the front surface 141. Optionally, the carrier substrate 100 may be placed horizontally to facilitate arrangement of the fingerprint chips 14 in a subsequent process.

In step S12, as shown in FIG. 3, a mold compound layer 15 covering all the fingerprint chips 14 is formed.

The mold compound layer 15 covers the solder bump 145. Optionally, an upper surface of the mold compound layer 15 is a horizontal surface.

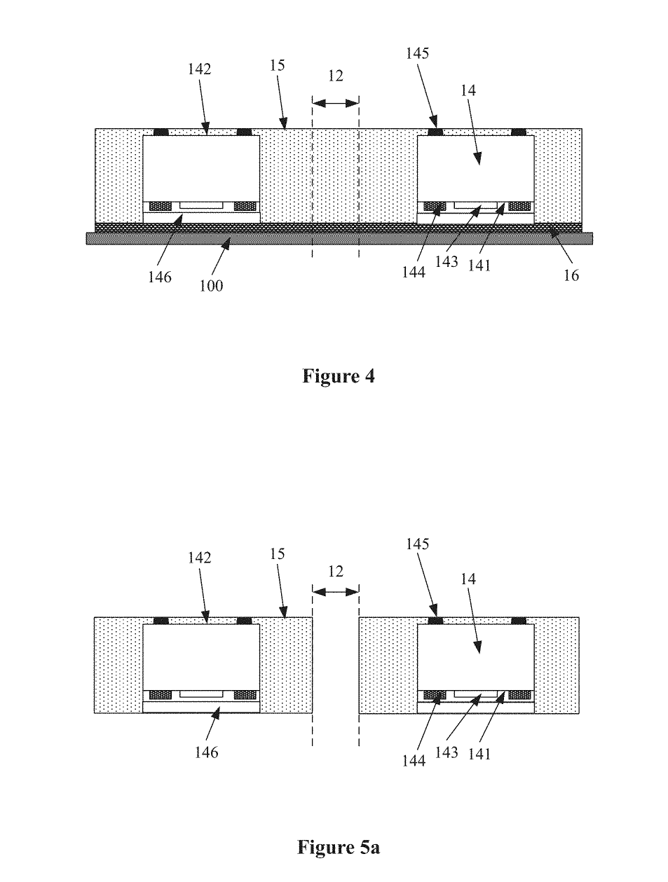

In step S13, as shown in FIG. 4, the mold compound layer 15 is gridded to expose the solder bumps 145 to facilitate electrical connection between the solder bump 145 and an external circuit.

The mold compound layer 15 has a first end surface and a second end surface opposite to each other. The solder hump 145 is exposed by the first end surface, and a top surface of the solder bump is flush with the first end surface. The outer surface is exposed by the second end surface, and is flush with the second end surface.

A thickness of the mold compound layer 15 removed by grinding is less than a thickness of the mold compound layer 15 on the back surface 142 of the fingerprint chip 14, and is greater than a thickness of the mold compound layer 15 on the solder bump 145. In this way, a part of the solder bump 145 is removed by grinding during the grinding process to fully expose the solder bump 145.

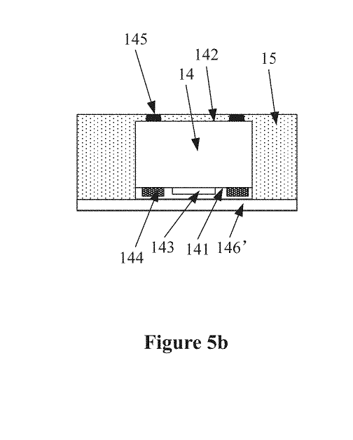

In step S14, as shown in FIG. 5a, the mold compound layer 15 is divided along the cutting trenches 12, to form multiple packages.

In the packaging method according the embodiment of the present disclosure, an adhesive film 16 is provided on a surface of the carrier substrate 100, and the fingerprint chips 14 are secured to the carrier substrate 100 by the adhesive film 16. The adhesive film 16 may be an adhesive tape or a photoresist layer.

In the embodiment shown in FIGS. 1 to 5a, the thickness of the formed package is less than the thickness of the fingerprint chip 14. The mold compound material forming the mold compound layer 15 has a great mechanical strength after being cured, thereby protecting the fingerprint chips 14.

In a case that no protection layer 146 is provided as the outer surface on the side of the front surface 141 of the fingerprint chip 14, based on the embodiment shown in FIGS. 1 to 5a, the packaging method according to the embodiment of the present disclosure further includes: forming a protection layer 146′ covering the outer surface and the second end surface of the mold compound layer before the mold compound layer 15 is cut. Then the cutting process is performed to form multiple packages. In this case, the protection layer 146′ covers the second end surface of the mold compound layer 15 and the outer surface. The formed package is shown in FIG. 5b.

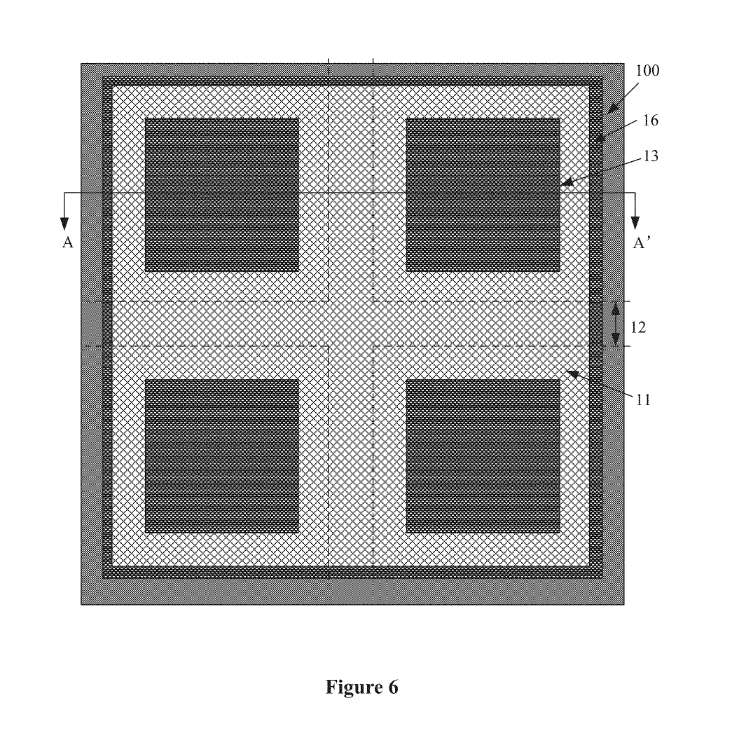

In the packaging method according to the embodiment of the present disclosure, the procedure of providing the multiple fingerprint chips 14 arranged in an array on the carrier substrate 100 may be shown in FIGS. 6 to 13, which are schematic diagrams showing a procedure of a fingerprint chip packaging method according to another embodiment of the present disclosure. The packaging method includes the following steps S21 to S25.

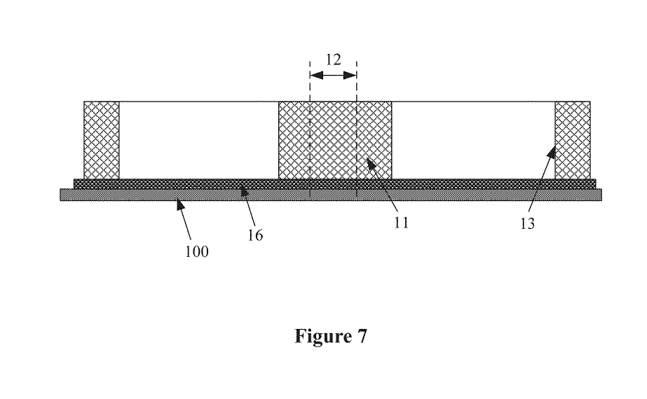

In step S21, as shown in FIGS. 6 and 7, a packaging substrate 11 is prepared.

FIG. 6 is a top view of the packaging substrate 11, and FIG. 7 is a sectional view taken along a line A-A′ in FIG. 6.

Multiple receiving holes 13 arranged in an array are formed in the packaging substrate 11. The cutting trenches 12 are arranged between adjacent ones of the receiving holes 13. On the packaging substrate 11, the receiving holes 13 are arranged in an array and are in one-to-one correspondence with the fingerprint chips 14 to receive the fingerprint chips 14.

The packaging substrate 11 is located on a surface of the carrier substrate 100. The adhesive film 16 is attached to a surface of the packaging substrate 11 facing the carrier substrate 100. In other embodiments, the packaging substrate 11 may be directly arranged on the surface of the carrier substrate 100 without providing the adhesive film 16.

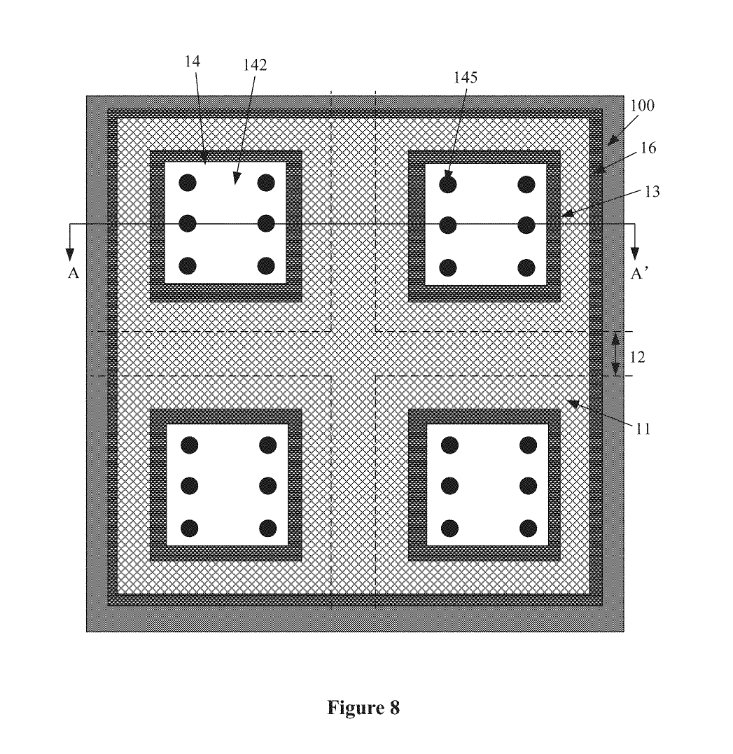

In step S22, as shown in FIGS. 8 to 10, one fingerprint chip 14 is arranged in each of the receiving holes 13.

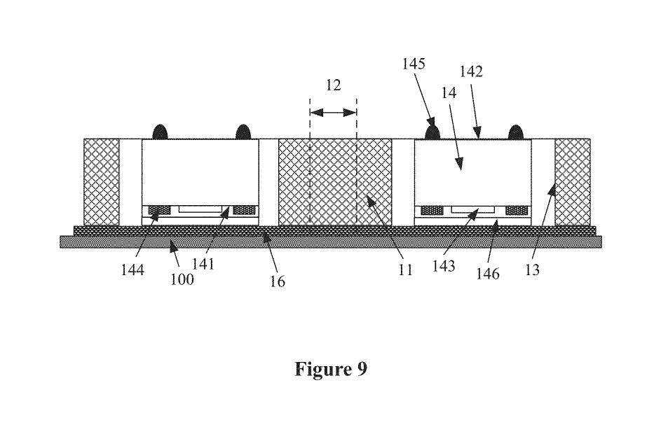

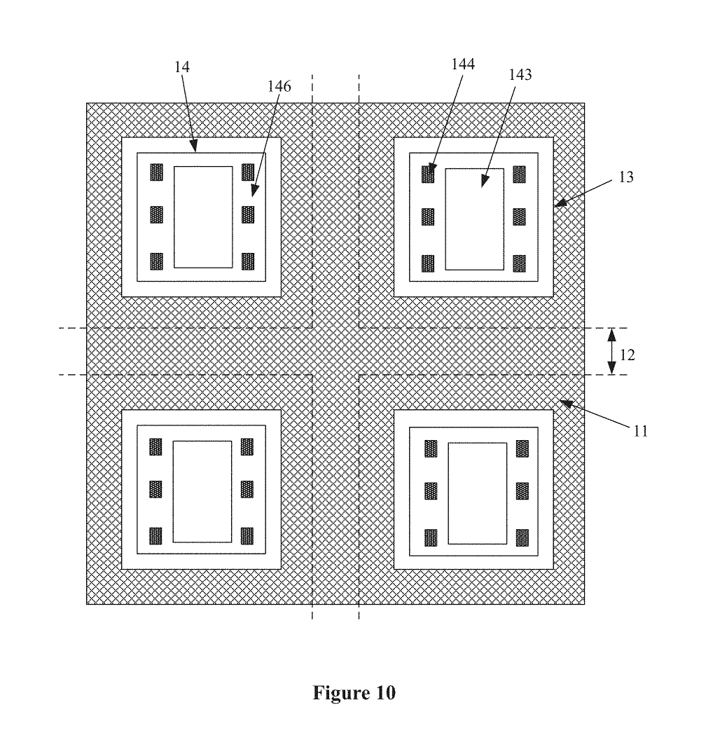

FIG. 8 is a top view showing the back surface 142 of the fingerprint chip 14 after the fingerprint chip 14 is arranged in the receiving hole 13. FIG. 9 is a sectional view taken along a line A-A′ in FIG. 8, and FIG. 10 is a top view showing the front surface 141 of the fingerprint chip 14 after the fingerprint chip 14 is arranged in the receiving hole 14. The solder bump 145 is located outside the receiving hole 13, that is, the solder bump 145 protrudes from the surface of the packaging substrate 11.

A surface of the carrier substrate 100 carrying the packaging substrate 11 is a flat surface, so that the lower end of the fingerprint chip 14 is flush with the lower surface of the packaging substrate 11. Therefore, after the mold compound layer 15 is subsequently formed, the lower surface of the packaging substrate 11, the lower end of the fingerprint chip 14, and the lower end of the mold compound layer 15 are flush with each other.

On one hand, the adhesive film 16 may be used for securing the fingerprint chip 14 in the receiving hole 13 to prevent movement of the fingerprint chip 14, which facilitates formation of the mold compound layer 15 in the subsequent process. On the other hand, in the subsequent grinding process, the adhesive film 16 may be removed after the grinding, so that the fingerprint chip 14 can be protected from being contaminated by debris generated during the grinding process.

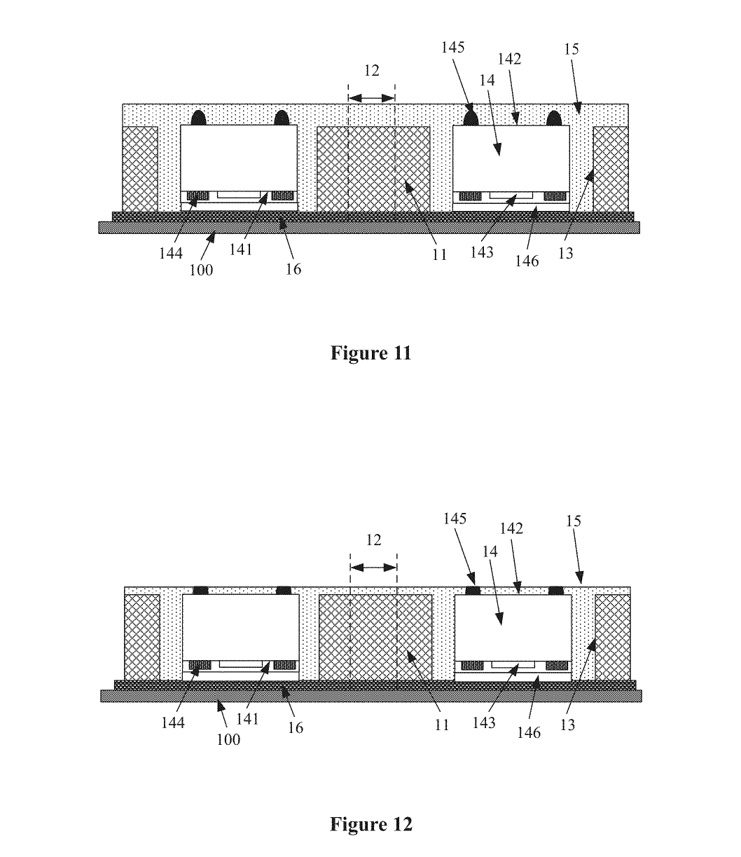

In step S23, as shown in FIG. 11, a mold compound layer 15 is formed on a surface of the packaging substrate 11 by which the solder bump 145 is exposed.

The mold compound layer 15 covers the back surfaces 142 of the fingerprint chips 14, and the receiving holes 13 are filled by the mold compound layer 15. The mold compound layer 15 covers the surface of the packaging substrate 11 by which the solder bumps 145 are exposed, and the back surfaces 142 of the fingerprint chips 14, and the receiving holes 13 are filled by the mold compound layer 15.

In step S24, as shown in FIG. 12, the mold compound layer 15 is gridded to expose the solder bumps 145.

A thickness of the mold compound layer 15 removed by grinding is less than a thickness of the mold compound layer 15 above the back surface 142 of the fingerprint chip 14, and is greater than a thickness of the mold compound layer 15 above the solder bump 145. A part of the solder bump 145 is removed by grinding to fully expose the solder bump 145, to facilitate electrical connection to an external circuit. The ground surface is a flat surface. Optionally, the solder bump 145 may be a solder ball or a solder pad.

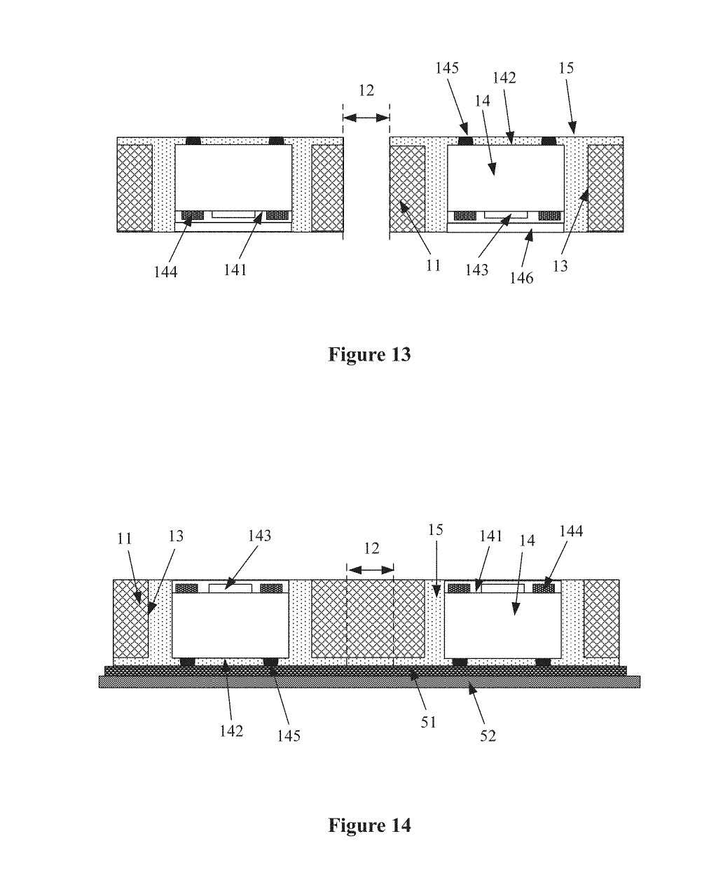

In step S25, as shown in FIG. 13, the packaging substrate 11 and the mold compound layer 15 are divided along the cutting trenches 12, to form multiple packages.

The packaging method further includes: removing the adhesive film 16 after the grinding and before the cutting; or removing the adhesive film 16 after the cutting. The cutting process may be performed by laser or with a slicing knife. In the embodiment of the present disclosure, the laser cutting process involving small cutouts is preferably adopted.

In the embodiment shown in FIGS. 6 to 13, the fingerprint chip 14 is a capacitive fingerprint chip. In the package, the front surface 141 of the fingerprint chip 14 is covered with a protection layer 146 having a dielectric constant greater than a set threshold. In this embodiment, the fingerprint chip 14 is provided with the protection layer 146 before being packaged. In this case, the providing multiple fingerprint chips 14 arranged in an array on the carrier substrate 100 includes: providing the multiple fingerprint chips 14, with the front surface 141 of each of the fingerprint chips 14 being covered with the protection layer 146. In this embodiment, the protection layer 146 is formed during fabrication of the fingerprint chip 14. The protection layer 146 covers the contact pad 144 and the sensing unit 143. In the formed package, the protection layer 146 does not cover the surface of the packaging substrate 11 corresponding to the front surfaces 141 of the fingerprint chips 14, and the second end surface of the mold compound layer 15.

In another embodiment, the protection layer may be formed after the mold compound layer is formed. In this case, the packaging method is shown in FIGS. 14 to 16, which are schematic diagrams showing a procedure of a fingerprint chip packaging method according to another embodiment of the present disclosure. In this embodiment, the fingerprint chip 14 is not provided with the protection layer, and the packaging method further includes the following steps S31 to S33.

In step S31, after the grinding process, as shown in FIG. 14, the mold compound layer 15 and the carrier substrate 100 are separated to remove the adhesive film 16 on the front surfaces 141 of the fingerprint chips 14, and the mold compound layer 15 secured with the fingerprint chips 14 is inverted, so that the front surfaces 141 of the fingerprint chips 14 face upwards.

The mold compound layer 15 secured with the fingerprint chips 14 may be placed on a surface of a carrier substrate 52, and the mold compound layer 15 may be secured with the carrier substrate 52 by an adhesive film 51.

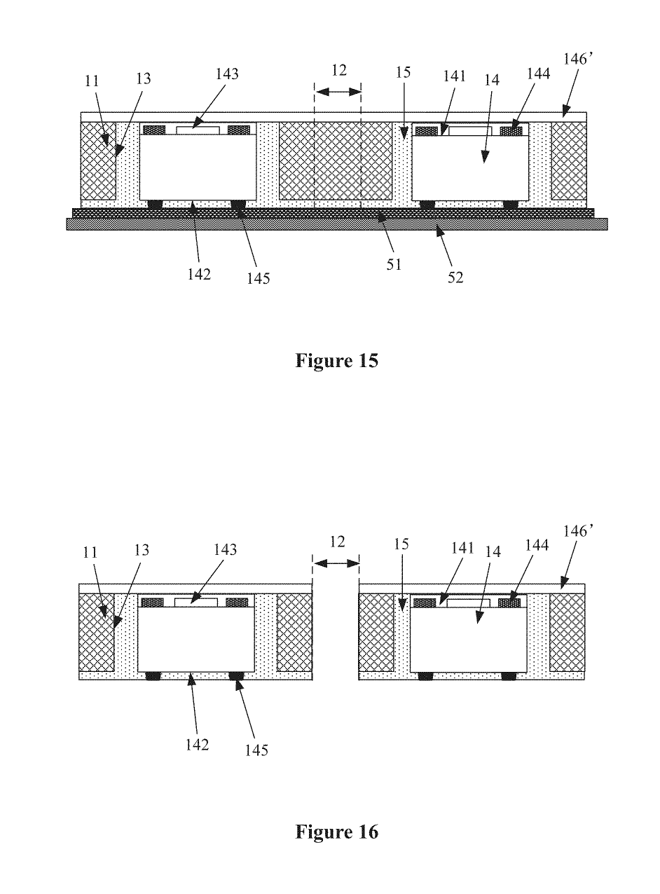

In step S32, as shown in FIG. 15, a protection layer 146′ covering the fingerprint chips 14 and the mold compound layer 15 is formed. In a case that the packaging substrate 11 is provided, the mold compound layer 15 further covers the surface of the packaging substrate 11 corresponding to the front surfaces 141 of the fingerprint chips 14.

in step S33, as shown in FIG. 16, the mold compound layer 15 is cut along the cutting trenches to form multiple packages.

The adhesive film 51 may be removed before cutting process, or the adhesive film 51 may be removed after the cutting process.

It should be noted that the case that the packaging substrate 11 is provided is described as an example in FIGS. 14 to 16. In a case that no packaging substrate 11 is provided, the protection layer 146′ formed after the mold compound layer 15 directly covers the surface of the mold compound layer 15 and the front surfaces 141 of the fingerprint chips 14, the implementation principle thereof is similar to that in the above embodiments. The formed package is shown in FIG. 5b, which is not illustrated herein.

The protection layer 146′ is formed on a surface of the packaging substrate 11 by which the front surfaces 141 of the fingerprint chips 14 are exposed, and the protection layer 146′ covers the front surfaces 141 of the fingerprint chips 14. In this case, the protection layer 146 covers not only the front surfaces 141 of the fingerprint chips 14 but also the surface of the packaging substrate 11 corresponding to the front surfaces 141 of the fingerprint chips 14 and the mold compound layer 15 located in the receiving holes 13.

In the case that the fingerprint chip 14 is a capacitive fingerprint chip, as described above, the package is provided with the protection layer. The set threshold is greater than or equal to 7, thus the protection layer has a high dielectric constant, which increases the sensing capacitance during the fingerprint recognition. With the provided protection layer having a high dielectric constant, the front surfaces of the fingerprint chips 14 can be protected, and the sensing capacitance can be increased by the protection layer having a high dielectric constant, which can not only eliminate the problem of the reduced capacitance caused by the increased distance, but also increase the accuracy and sensitivity of fingerprint recognition. Due to the protection layer, the spacing between a finger and the sensing unit 143 is increased, which results in the reduced sensing capacitance. Therefore, a protection layer with a high dielectric constant is required, so that the sensing capacitance in the case that the protection layer is provided is not less than the sensing capacitance in the case that no protection layer is provided. In this way, the sensing capacitance is increased while ensuring that the front surfaces of the fingerprint chips 14 are not contaminated, thereby eliminating the problem of the reduced capacitance caused by the increased distance.

In the embodiment of the present disclosure, the distance from the back surface 142 of the fingerprint chip 14 to a lower surface of the package is equal to or less than the thickness of the packaging substrate 11. In the case that the fingerprint chip 14 is provided with the protection layer 146, the lower surface of the package is an outer surface of the protection layer 146. In the case that the fingerprint chip 14 is not provided with the protection layer 146 and a protection layer 146′ is formed after the mold compound layer 15, the lower surface of the package is an outer surface on which the sensing unit 143 and the contact pad 144 that are provided on the front surface 141 of the fingerprint chip 14 are located.

The packaging substrate 11 has a first surface and a second surface. The providing one fingerprint chip 14 in each of the receiving holes 13 includes: arranging the fingerprint chip 14 in the receiving hole 13, with an end surface of the fingerprint chip corresponding to the front surface being flush with the first surface, and the solder hump protruding from the second surface. In this way, the surface of the formed package corresponding to the front surfaces 141 of the fingerprint chips 14 is a flat surface, so that the formed package can be easily integrated with the electronic device to perform the fingerprint recognition.

In the embodiment of the present disclosure, the packaging substrate 11 includes a base carrying a mold compound material for forming the mold compound layer. The base functions as a supporting structure, to facilitate formation of the mold compound layer 15. The base is a plate structure having the receiving holes 13, which ensures the flatness of the upper surface of the mold compound layer 15 and the flatness of the lower surface of the package.

Optionally, the packaging substrate further includes multiple interconnection circuits provided on a surface of the base in one-to-one correspondence with the fingerprint chips. The interconnection circuit is configured to be electrically connected to an external circuit and/or electronic component. The interconnection circuit may be located on a surface of the base corresponding to the front surfaces 141 of the fingerprint chips 14 or a surface of the base corresponding to the back surfaces 142 of the fingerprint chips 14. With the interconnection circuit, a part of circuit structures and/or electronic components of the electronic device on which the package is mounted may be arranged on the surface of the base, to improve the integration of the electronic device, thereby facilitating miniaturization of the electronic device. In this case, the packaging substrate 11 is a silicon substrate or a PCB.

The base of the PCB may be implemented in various forms, such as a glass fiber board, a paper substrate, a metal substrate, a plastic substrate, and a high frequency PTFE board. The base of the PCB may be classified into organic materials and inorganic materials according to the material. The organic materials include phenolic resin, glass fiber/epoxy resin, Polyimide, BT/Epoxy, and the like. The inorganic materials include aluminum, Copper-invar-copper, ceramic, and the like. The base is selected depending on the heat dissipation performance, the inorganic materials may be adopted due to the excellent heat dissipation performance. The base of the PCB may also be classified into hard boards and soft boards according to hardness of the finished product. The base of the PCB may also be classified according to the structures. The base of the PCB may also be classified according to the use applications, mainly including bases for communication, consumable electronics, military, computer, semiconductor, electric measuring board, and the like.

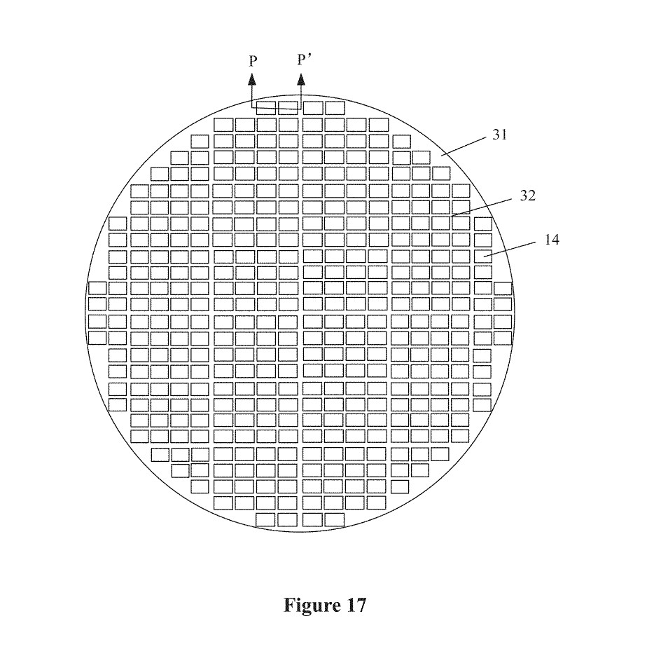

In the packaging method according to the embodiment of the present disclosure, the procedure of providing multiple fingerprint chips 14 arranged in an array on the carrier substrate 100 may be as shown in FIGS. 17 to 24, which are schematic diagrams showing a method for fabricating a fingerprint chip according to an embodiment of the present disclosure. The method includes the following steps S41 to S46.

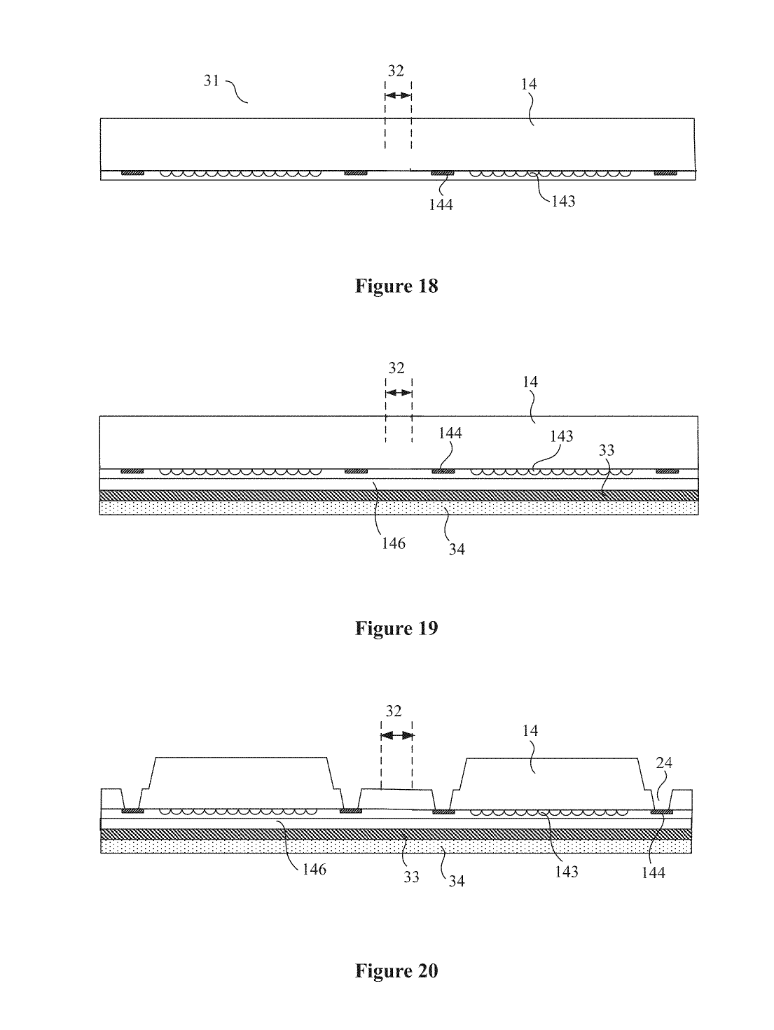

In step S41, as shown in FIG. 17 and FIG. 18, a wafer 31 is prepared.

FIG. 17 is a top view showing a surface of the wafer 31 corresponding to the front surface of the fingerprint chip 14, and FIG. 18 is a sectional view taken along a line P-P′ in FIG. 17. The wafer 31 is provided with multiple fingerprint chips 14 arranged in an array. Cutting gaps are arranged between adjacent ones of the fingerprint chips 14. The contact pad 144 and the sensing unit 143 are provided on a front surface of each of the fingerprint chips 14.

In step S42, as shown in FIG. 19 and FIG. 20, a through hole 24 for exposing the contact pad 144 is formed on the back surface of each of the fingerprint chips 14 by a TSV process.

First, as shown in FIG. 19, the wafer 31 is inverted so that the front surfaces of the fingerprint chips 14 face downwards. The wafer 31 is located on a surface of a carrier substrate 34. In order to prevent movement of the wafer 31, the wafer 31 is secured to the surface of the carrier substrate 34 by an adhesive film 33. Before the through hole 24 is formed, the back surface of the wafer 31 is thinned to form a thinned fingerprint chip.

Then, as shown in FIG. 20, the through hole 24 by Which the contact pad 144 is exposed is formed on the back surface of each of the fingerprint chip 14 by an etching process. In the embodiment of the present disclosure, the through hole 24 is a stepped through hole including two steps. A groove having a depth less than a thickness of the wafer 31 is formed at a position of the wafer 31 corresponding to the contact pad 144, and then a via hole extending through the wafer 31 is formed in the groove, to expose the contact pad 144.

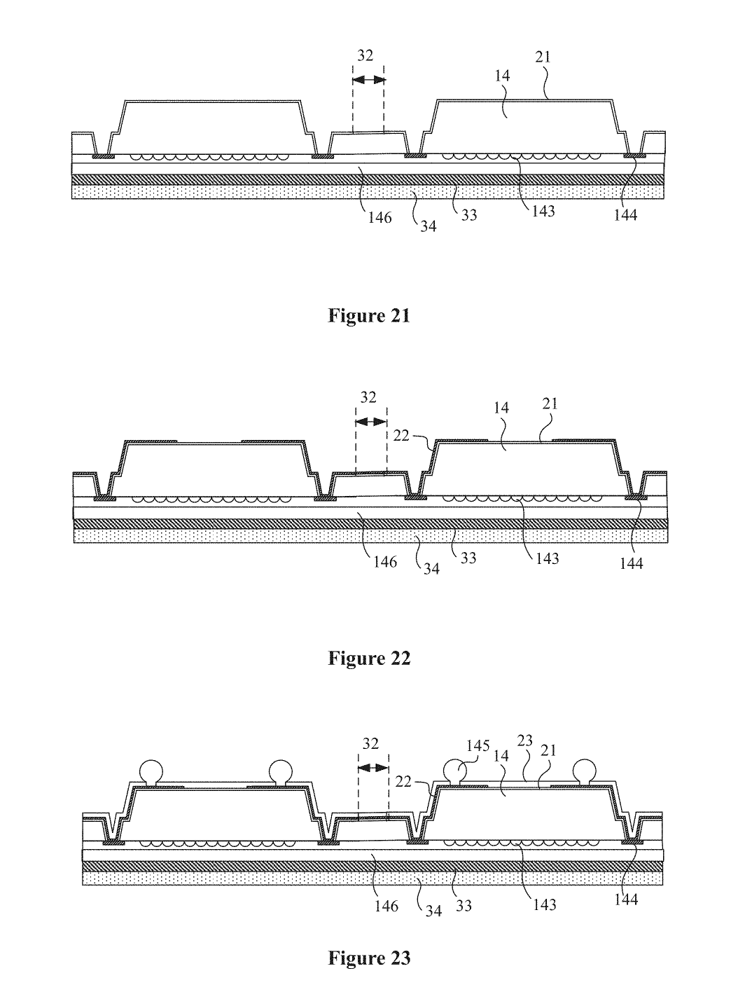

In step S43, as shown in FIG. 21, an insulating layer 21 is formed on the back surface of each of the fingerprint chips 14. The insulating layer 21 covers a sidewall of the through hole 24. In an embodiment, the insulating layer 21 extends outside the through hole 24.

The insulating layer may cover the back surface of the entire wafer 31, and has an opening corresponding to the bottom of the through hole, to expose the contact pad 144.

In step S44, as shown in FIG. 22, a rewiring layer 22 is formed on a surface of the insulating layer 21. The rewiring layer 22 is electrically connected to the contact pad 144 at the bottom of the through hole 24 and extends outside the through hole 24.

In step S45, as shown in FIG. 23, a solder mask 23 is formed on a surface of the rewiring layer 22. An opening is provided in the solder mask to expose the rewiring layer 22. The solder bump 145 is located in the opening and is electrically connected to the rewiring layer 22.

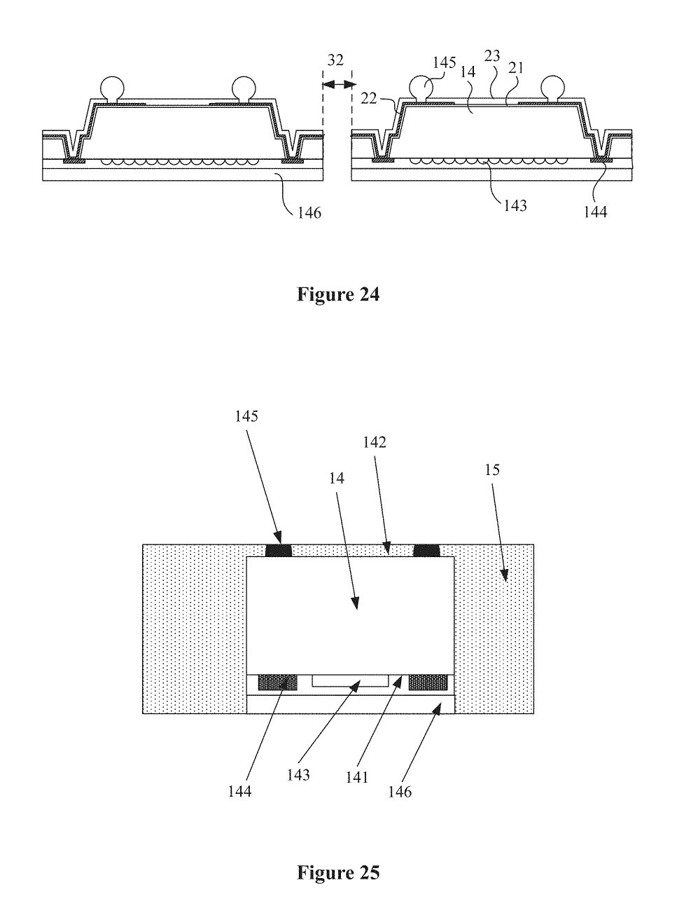

In step S46, as shown in FIG. 24, the wafer 31 is cut along the cutting gaps 32 to form the multiple fingerprint chips 14.

In the implementation shown in FIGS. 17 to 24, before the wafer 31 is cut, the method further includes: forming a protection layer 146 having a high dielectric constant on the front surface of the wafer. The protection layer 146 covers front surfaces of all the fingerprint chips 14. The protection layer 146 may be formed before the back surface structures of the fingerprint chip 14 are formed. Alternatively, the protection layer 146 may be formed after the back surface structures of the fingerprint chip 14 are formed, and then the wafer 31 is cut. In other embodiments described above, the protection layer 146 is not formed during fabrication of the fingerprint chip 14, and a protection layer 146′ is formed after the mold compound layer 15 is formed and before the mold compound layer 15 is cut.

In the process of packaging the fingerprint chips by the packaging method according to the embodiment of the present disclosure, the packaging substrate 11 serves as a supporting structure for the mold compound material and has receiving holes 13 for receiving the fingerprint chips 14, and the thickness of the formed package is equal to the thickness of the fingerprint chip. With the technical solutions according to the embodiment of the present disclosure, the thickness of the package is greatly reduced as compared with the fingerprint chip packaging process in the conventional technology in which the chip is secured to the circuit board. Further, since the mold compound layer 15 formed after curing of the mold compound material has a great mechanical strength, the mold compound layer 15 can serve as a carrier substrate for mounting other electronic components of the electronic device. The electronic components may be electrically connected to a main board circuit of the electronic device and is driven by the main board circuit of the electronic device, or may be driven by the interconnection circuit provided on the surface of the base, such that the integration of the electronic device is greatly improved, the space of the circuit board is saved, thereby facilitating the miniaturization of the electronic device.

Based on the packaging method embodiment described above, a fingerprint chip package is further provided according to an embodiment of the present disclosure. The fingerprint chip package is shown in FIG. 25, which is a schematic structural diagram of a fingerprint chip package according to an embodiment of the present disclosure. The package includes a fingerprint chip 14. The fingerprint chip 14 has a front surface 141 and a back surface 142 opposite to each other. A sensing unit 143 and a contact pad 144 electrically connected to the sensing unit 143 are provided on the front surface 141 of the fingerprint chip 14. A solder bump 145 is provided on the back surface 142 of the fingerprint chip 14. The solder bump 145 is electrically connected to the contact pad 144. The package further includes a mold compound layer 15 covering a side surface and the back surface of the fingerprint chip 14. The solder bump 145 is exposed by the mold compound layer 15. In the package according to the embodiment of the present disclosure, an outer surface of the package corresponding to the front surface 141 of the fingerprint chip 14 and an outer surface of the package corresponding to the back surface 142 of the fingerprint chip 14 are flat surfaces.

The package shown in FIG. 25 is formed by the packaging method shown in FIGS. 1 to 5a, and has a small thickness. A surface of the mold compound layer 15 close to a sensing outer surface of the fingerprint chip 14 is flush with the sensing outer surface, and a surface of the mold compound layer 15 close to the solder bump 145 is flush with the solder bump 145, so that the thickness of the entire mold compound structure is slightly less than the thickness of the fingerprint chip 14.

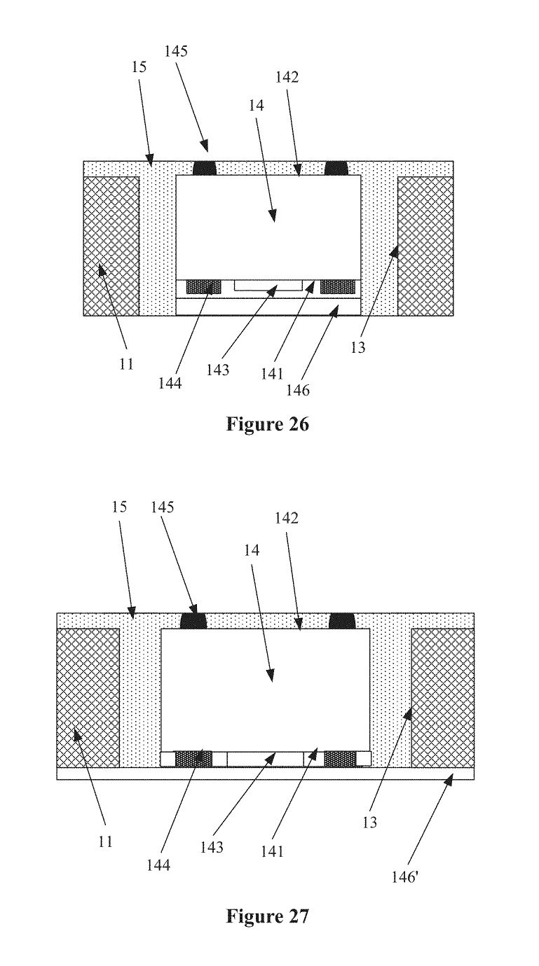

Reference is made to FIG. 26, which is a schematic structural diagram showing a chip package according to another embodiment of the present disclosure. The package shown in FIG. 26 further includes a packaging substrate 11 based on the embodiment shown in FIG. 25. A receiving hole 13 is provided in the packaging substrate 11. The fingerprint chip 14 is located in the receiving hole 13, and the solder bump 145 is located outside the receiving hole 13. The mold compound layer 15 covers a surface of the packaging substrate 11 by which the solder bump 145 is exposed, and the receiving hole 13 is filled by the mold compound layer 15. As compared with the embodiment shown in FIG. 25 in which only the mold compound layer 15 is used for packaging, the packaging substrate 11 as a supporting structure is further provided in the embodiment shown in FIG. 26 for carrying the mold compound layer 15 which is used for molding. Further, the packaging substrate 11 has the receiving hole 13 for receiving the fingerprint chip 14, to provide a better package effect. The package shown in FIG. 26 may be formed by the packaging method shown in FIGS. 6 to 13.

The package shown in FIG. 26 includes a packaging substrate 11, a fingerprint chip 14, and a mold compound layer 15. A receiving hole 13 is provided in the packaging substrate 11 The fingerprint chip 14 is located in the receiving hole 13. The fingerprint chip 14 has a front surface 141 and a back surface 142 opposite to each other. A sensing unit 143 and a contact pad 144 electrically connected to the sensing unit 143 are provided on the front surface 141 of the fingerprint chip 14. A solder bump 145 is provided on the back surface 142 of the fingerprint chip 14. The solder bump 145 is electrically connected to the contact pad 144. The solder bump 145 is located outside the receiving hole 13. The mold compound layer 15 covers a surface of the packaging substrate 11 by which the solder bump 145 is exposed, and covers the back surface 142 of the fingerprint chip 14, and the receiving hole 13 is filled by the mold compound layer 15 The solder bump 145 is exposed by the mold compound layer 15.

A thickness of the mold compound layer 15 covering the back surface 142 of the fingerprint chip 14 is less than a thickness of the solder bump 145, to facilitate electrical connection between the solder bump 145 and an external circuit. Further, with the mold compound layer 15, the back surfaces 142 of the fingerprint chips 14 can be protected.

As shown in FIG. 26, the package further includes a protection layer 146 having a dielectric constant greater than a set threshold. The protection layer 146 covers the front surfaces 141 of the fingerprint chips 14. In the embodiment shown in FIG. 26, the protection layer 146 is formed fabrication of the fingerprint chip 14. During fabrication of the fingerprint chip 14, the protection layer is formed on a surface of the wafer corresponding to the front surface of the fingerprint chip. The protection layer covers front surfaces of all fingerprint chips in the wafer, such that front surfaces of single fingerprint chips formed after a cutting process each have the protection layer.

The set threshold is greater than or equal to 7, so that the protection layer 146 has a high dielectric constant, thereby protecting the front surfaces of the fingerprint chips 14 from being damaged and contaminated, increasing the sensing capacitance, and thus improving accuracy and sensitivity of the fingerprint detection.

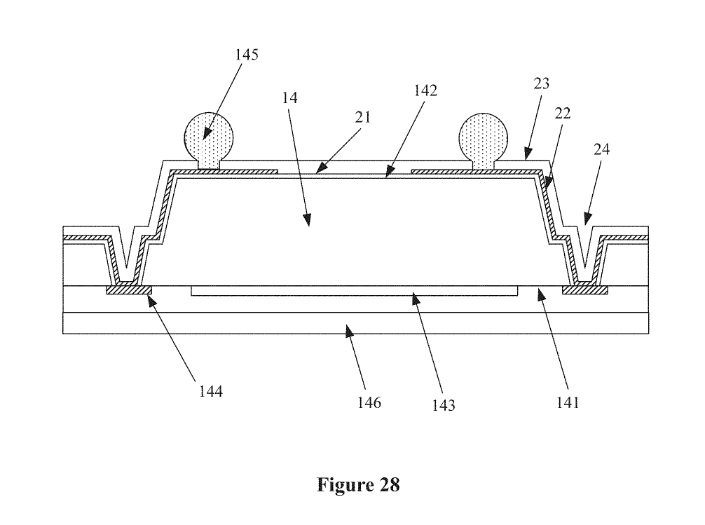

Reference is made to FIG. 27, which is a schematic structural diagram showing a fingerprint chip package according to another embodiment of the present disclosure. The embodiment shown in FIG. 27 differs from the embodiment shown in FIG. 26 in that no protection layer 146 is formed on the surface of the fingerprint chip 14 when the fingerprint chip 14 is fabricated from a wafer, and a protection layer 146′ is formed after the mold compound layer 15 in the process of packaging the fingerprint chip 14. In this case, the protection layer 146′ not only covers the front surface 141 of the fingerprint chip 14, but also covers a surface of the packaging substrate 11 corresponding to the front surfaces 141 of the fingerprint chips 14. The package shown in FIG. 27 may be formed by the packaging method shown in FIGS. 14 to 16.

In the packages according to the embodiments of the present disclosure, as described in the above embodiments, the packaging substrate 11 is formed by cutting a large-sized packaging substrate. The packaging substrate 11 has a first surface and a second surface. An end surface of the package corresponding to the front surface 141 of the fingerprint chip 14 is flush with the first surface, and the solder bump 145 is exposed by the second surface. In the case that the fingerprint chip 14 is provided with the protection layer 146, as shown in FIG. 6, the protection layer 146 is flush with the first surface. In the case that no protection layer 146 is provided on the fingerprint chip 14, the contact pad 144 is flush with the second surface, and the protection layer 146′ is formed during the packaging process. The protection layer 146′ covers the fingerprint chip 14, the first surface, and the mold compound layer 15 located at the lower end of the receiving hole 13.

In an embodiment, the packaging substrate includes a base carrying a mold compound material to form the mold compound layer. Further, in order to facilitate the miniaturization and/or circuit interconnection of the electronic device, the packaging substrate 11 further includes an interconnection circuit (which is not shown in the drawings of the embodiments of the present disclosure) provided on a surface of the base. The interconnection circuit is configured to be electrically connected to an external circuit and/or electronic component. In this case, the packaging substrate 11 may be an FPC or a PCB.

In the embodiment of the present disclosure, an interconnection structure may be formed on the back surface of the fingerprint chip 14 by a TSV process, so that the solder bump 145 is electrically connected to the contact pad 144. The interconnection structure on the back surface of the fingerprint chip is shown in FIG. 28.

Reference is made to FIG. 28, which is a schematic structural diagram of an interconnection structure on a back surface of a fingerprint chip according to an embodiment of the present disclosure. In the embodiment shown in FIG. 28, a through hole 24 is formed on the back surface 142 of the fingerprint chip 14 by a TSV process, to expose the contact pad 144 located on the front surface 141 of the fingerprint chip 14. The through hole 24 and the back surface 142 of the fingerprint chip 14 are covered with an insulating layer 21. The insulating layer 21 is provided with an opening at a position corresponding to the bottom of the through hole 24 to expose the contact pad 144. The surface of the insulation layer 21 is covered with a rewiring layer 22. The rewiring layer 22 is electrically connected to the contact pad 144 at the bottom of the through hole 24, and extends to a flat region of the back surface 142 in which no through hole 24 is provided. The rewiring layer 22 and a region of the back surface 142 which is not covered with the rewiring layer 22 are covered with a solder mask 23. The solder mask 23 is provided with an opening at a position corresponding to the flat region of the back surface 142 in which no through hole 24 is provided, to receive the solder bump 145.

In the implementation shown in FIG. 28, the protection layer 146 is directly formed on the front surface of the fingerprint chip 14. In other embodiments, the protection layer 146 may also be formed during the process of packaging the fingerprint chip 14. That is, the fingerprint layer 14 is provided with the protection layer 146, and the protection layer 146′ is formed when the fingerprint chip is packaged.

The package according to the embodiment of the present disclosure is applied to an electronic device having a fingerprint recognition function, and the electronic device may be a touch device such as a mobile phone and a tablet computer.

In the package according to the embodiment of the present disclosure, the packaging substrate 11 serves as a support structure for carrying the mold compound layer 15 and has a receiving hole for receiving the fingerprint chip, and the thickness of the formed package is equal to the thickness of the fingerprint chip 14. In the existing fingerprint chip package, the fingerprint chip and the circuit board need to be secured to each other, and the thickness of the formed package is equal to a sum of thicknesses of the circuit board, the fingerprint chip and an electrical connection layer between the circuit board and the fingerprint chip. With the technical solutions according to the embodiment of the present disclosure, the thickness of the package is greatly reduced as compared with the conventional technology. Further, since the mold compound layer 15 formed after curing of the mold compound material has a great mechanical strength, the mold compound layer 15 can serve as a carrier substrate for mounting other electronic components of the electronic device. The electronic components may be electrically connected to a main board circuit of the electronic device and is driven by the main board circuit of the electronic device, or may be driven by the interconnection circuit provided on the surface of the base, such that the integration of the electronic device is greatly improved, the space of the circuit board of the electronic device is saved, and more functional electronic components can be integrated, thereby facilitating the miniaturization of the electronic device.

Embodiments in this specification are described in a progressive manner, each of the embodiments emphasizes differences from other embodiments, and the same or similar parts among the embodiments can be referred to each other. For the package disclosed in the embodiments, since the package corresponds to the packaging method disclosed in the embodiments, the description is relatively simple, and the related parts can be referred to the description of the package method.

With the above descriptions of the disclosed embodiments, the skilled in the art may practice or use the present disclosure. Various modifications to the embodiments are apparent for the skilled in the art. The general principle suggested herein can be implemented in other embodiments without departing from the spirit or scope of the disclosure. Therefore, the present disclosure should not be limited to the embodiments disclosed herein, but has the widest scope that is conformity with the principle and the novel features disclosed herein.

1. A fingerprint chip packaging method, comprising:
providing a plurality of fingerprint chips arranged in an array on a carrier substrate, wherein each of the fingerprint chips has a front surface and a back surface opposite to each other, a sensing unit and a contact pad electrically connected to the sensing unit are provided on the front surface of the fingerprint chip, a solder bump electrically connected to the contact pad is provided on the back surface of the fingerprint chip, the solder bump faces upwards, and cutting trenches are arranged between adjacent ones of the fingerprint chips;
forming a mold compound layer covering the plurality of fingerprint chips;
grinding the mold compound layer to expose the solder bump to facilitate electrical connection between the solder bump and an external circuit; and
dividing the mold compound layer along the cutting trenches to form a plurality of packages.

2. The fingerprint chip packaging method according to claim 1, wherein an adhesive film is provided on a surface of the carrier substrate, and the fingerprint chips are secured to the carrier substrate by the adhesive film.

3. The fingerprint chip packaging method according to claim 1, wherein the providing the plurality of fingerprint chips arranged in an array on the carrier substrate comprises:
preparing a packaging substrate, wherein the packaging substrate is provided with a plurality of receiving holes arranged in an array, and
providing one fingerprint chip in each of the receiving holes, wherein
the solder bump protrudes from a surface of the packaging substrate, and
the mold compound layer covers the packaging substrate, and the receiving holes are filled with the mold compound layer.

4. The fingerprint chip packaging method according to claim 3, wherein the providing one fingerprint chip in each of the receiving holes comprises:
providing an adhesive film on a surface of the packaging substrate facing the carrier substrate, wherein the fingerprint chips are secured by the adhesive film.

5. The fingerprint chip packaging method according to claim 2, further comprising:
removing the adhesive film after the grinding and before the cutting; or
removing the adhesive film after the cutting.

6. The fingerprint chip packaging method according to claim 1, wherein the fingerprint chips are capacitive fingerprint chips, and a front surface of each of the fingerprint chips in the packages is covered with a protection layer having a dielectric constant greater than 7.

7. The fingerprint chip packaging method according to claim 6, further comprising:
inverting the mold compound layer in which the plurality of fingerprint chips are secured after the grinding, so that the front surface of each of the fingerprint chips faces upwards; and
forming the protection layer covering the fingerprint chips and the mold compound layer.

8. The fingerprint chip packaging method according to claim 6, wherein the providing the plurality of fingerprint chips arranged in an array on the carrier substrate comprises:
preparing the plurality of fingerprint chips, with the front surface of each of the fingerprint chips being covered with the protection layer.

9. The fingerprint chip packaging method according to claim 3, wherein the packaging substrate has a first surface and a second surface, and the providing one fingerprint chip in each of the receiving holes comprises:
arranging the fingerprint chip in the receiving hole, with an end surface of the fingerprint chip corresponding to the front surface being flush with the first surface, and the solder bump protruding from the second surface.

10. The fingerprint chip packaging method according to claim 3, wherein the packaging substrate comprises a base configured to carry a mold compound material for forming the mold compound layer.

11. The fingerprint chip packaging method according to claim 10, wherein the packaging substrate further comprises a plurality of interconnection circuits provided on a surface of the base, the plurality of interconnection circuits are in one-to-one correspondence with the fingerprint chips, and are configured to be electrically connected to an external circuit and/or electronic component.

12. The fingerprint chip packaging method according to claim 13, wherein the packaging substrate is a silicon substrate or a printed circuit board (PCB).

13. The fingerprint chip packaging method according to claim 1, wherein the providing the plurality of fingerprint chips arranged in an array on the carrier substrate comprises:
preparing a wafer, wherein the wafer is provided with a plurality of fingerprint chips arranged in an array, cutting gaps are provided between adjacent ones of the fingerprint chips, and the contact pad and the sensing unit are provided on the front surface of each of the fingerprint chips,
forming a through hole by which the contact pad is exposed on the back surface of each of the fingerprint chips by an etching process,
forming an insulating layer on the back surface of each of the fingerprint chips, wherein the insulating layer covers a sidewall of the through hole,
forming a rewiring layer on a surface of the insulating layer, wherein the rewiring layer is electrically connected to the contact pad at a bottom of the through hole and is extended outside the through hole,
forming a solder mask on a surface of the rewiring layer, wherein an opening is provided in the solder mask to expose the rewiring layer, and the solder bump is located in the opening and is electrically connected to the rewiring layer, and
cutting the wafer along the cutting gaps to form the plurality of fingerprint chips.

14. A fingerprint chip package, comprising:
a fingerprint chip, wherein the fingerprint chips comprise a front surface and a back surface opposite to each other, a sensing unit and a contact pad electrically connected to the sensing unit are provided on the front surface of the fingerprint chip, and a solder bump electrically connected to the contact pad is provided on the back surface of the fingerprint chip; and
a mold compound layer covering a side surface and the back surface of the fingerprint chip, wherein the solder hump is exposed by the mold compound layer.

15. The fingerprint chip package according to claim 14, further comprising:
a packaging substrate provided with a receiving hole, wherein
the fingerprint chip is located in the receiving hole, the solder bump is located outside the receiving hole, the mold compound layer covers a surface of the packaging substrate by which the solder bump is exposed, and the receiving hole is filled with the mold compound layer.

16. The fingerprint chip package according to claim 15, further comprising:
a protection layer having a dielectric constant greater than a set threshold, wherein the protection layer covers the front surface of the fingerprint chip.

17. The fingerprint chip package according to claim 16, wherein the protection layer further covers a surface of the packaging substrate corresponding to the front surface of the fingerprint chip.

18. The fingerprint chip package according to claim 16, wherein the set threshold is greater than or equal to 7.

19. The fingerprint chip package according to claim 15, wherein the packaging substrate has a first surface and a second surface, an end surface of the fingerprint chip corresponding to the front surface is flush with the first surface, and the solder bump is exposed by the second surface.

20. The fingerprint chip package according to claim 15, wherein the packaging substrate comprises a base carrying a mold compound material for forming the mold compound layer.

21. The fingerprint chip package according to claim 20, wherein the packaging substrate further comprises an interconnection circuit provided on a surface of the base, and the interconnection circuit is configured to be electrically connected to an external circuit and/or electronic component.

22. The fingerprint chip package according to claim 14, wherein a through hole is provided on the back surface of the fingerprint chip, and the fingerprint chip package further comprises:
an insulation layer covering a sidewall of the through hole,
a rewiring layer covering the insulating layer, wherein the rewiring layer is electrically connected to the contact pad at a bottom of the through hole and is extended outside the through hole, and
a solder mask covering the rewiring layer, wherein an opening is provided in the solder mask to expose the rewiring layer, and the solder bump is located in the opening and is electrically connected to the rewiring layer.

23. The fingerprint chip package according to claim 15, wherein the packaging substrate is a silicon substrate or a printed circuit board (PCB).
